(19) United States
(12) Patent Application Publication
(10) Pub. No.: US 2026/0358434 A1
(43) Pub. Date: Nov. 12, 2026

(54) Method and test circuit for testing a DC voltage source in a drive system, power converter arrangement, and drive system

(71) Applicant: SEG Automotive Germany GmbH, Stuttgart (DE)

(72) Inventor: Nima SAADAT, Stuttgart (DE)

(21) Appl. No.: 19/464,231

(22) Filed: Jan. 29, 2026

(30) Foreign Application Priority Data
Jan. 29, 2025 (DE) 102025103220.3

(51) Int. Cl. G01R 31/40; G01R 31/00

(52) U.S. Cl. CPC G01R 31/40; G01R 31/006

(57) ABSTRACT

A method for testing a DC voltage source in a drive system including the DC voltage source, a DC link capacitor arrangement connected in parallel with the DC voltage source and a converter circuit connected in parallel with the DC link capacitor arrangement, with a DC voltage side and an AC volt-age side includes generating an injection signal using the test circuit; injecting the generated injection signal using the test circuit into the DC voltage side; determining a voltage or current signal on the DC voltage side as a test signal in response to the injection of the injection signal; evaluating the test signal by the test circuit as to whether the test signal reaches a threshold value; and determining whether the DC voltage source is connected to the DC link capacitor unit and the converter circuit or not, depending on the evaluation of the test signal.

### RELATED APPLICATION

This application claims priority to German Application No. 10 2025 103 220.3, filed on Jan. 29, 2025, which is hereby incorporated by reference in its entirety.

### DESCRIPTION

The present disclosure relates to a method for testing a DC voltage source in a drive system, a test circuit and a computer program for performing the method as well as a power converter assembly and a drive system.

### BACKGROUND

In a drive system, such as one that can be used as a traction drive in a vehicle, for example, a converter circuit comprising a plurality of half-bridges with high-side and low-side switching elements may be provided for the rectification or inversion of current between a DC voltage source connected to a DC voltage side, e.g. a vehicle battery or a DC voltage on-board network, and a multi-phase electric machine connected to an AC voltage side. Furthermore, a DC link capacitor arrangement comprising a plurality of capacitors may be connected in parallel between the DC voltage source and the converter circuit. It can be of great importance to detect early when the DC voltage source is no longer connected to the remaining components of the drive system, e.g. due to a defect or an accident.

### SUMMARY

According to the disclosure, a method for testing a DC voltage source in a drive system, a test circuit and a computer program for performing the method as well as a power converter assembly and a drive system having the features of the independent claims are proposed. Advantageous embodiments are the subject matter of the dependent claims as well as of the following description.

The drive system can in particular be used in a (motor) vehicle, e.g. as a traction drive. The drive system comprises the DC voltage source to be tested, e.g. a vehicle battery or a DC voltage on-board network, as well as a power converter assembly connected in parallel with the DC voltage source. The power converter assembly has two DC voltage contacts for connecting the DC voltage source and a plurality of AC voltage contacts for connecting an electric machine, wherein the DC voltage source is connected in parallel with the DC voltage contacts of the power converter assembly. The DC voltage source can be connected to the DC voltage contacts of the power converter assembly by means of cables or lines.

The power converter assembly has a DC link capacitor arrangement connected in parallel with the DC voltage contacts and a converter circuit connected in parallel with the DC link capacitor arrangement, with a DC voltage side and an AC voltage side. The DC link capacitor arrangement may comprise one or more individual capacitors. The converter circuit and the DC link capacitor arrangement may, in particular together with a computing unit or a control unit, form a structural unit or a device that is referred to as a power converter assembly or inverter.

A converter circuit shall be understood in particular as a circuit with an AC voltage side and a DC voltage side that is configured to convert current between the AC voltage side and the DC voltage side. The converter circuit has in particular a number of half-bridges consisting of two switching elements connected in series, wherein the DC voltage side is formed by an upper (high side) and lower (low side) terminal of the half-bridges and the AC voltage side is formed by centre taps of the half-bridges. The switching elements may in particular comprise semiconductor switches that can each be opened (non-conducting) and closed (conducting) in accordance with a control signal. The semiconductor switches may comprise MOSFETs or IGBTs, for example gallium nitride (GaN) or silicon carbide (SIC) FETs. Furthermore, the DC link capacitor arrangement may be part of a DC link, wherein this DC link may further comprise, for example, one or more loads that may be connected in parallel with the DC voltage source and the DC link capacitor arrangement. The DC voltage source and this DC link may be part of a DC voltage network. Such a DC voltage network may for example be a low-voltage network or a high-voltage network. The high-voltage network and the low-voltage network may be coupled in the vehicle via a suitable DC/DC converter. The rated voltage level of the high-voltage network (hereinafter also referred to as high-voltage level) may for example be significantly greater than a permissible contact voltage, in particular 60 V, e.g. up to several hundred volts. For example, high-voltage levels of 400 V or 800 V are frequently used in current electric vehicles. The rated voltage level of the low-voltage network may for example correspond to conventional vehicle low voltages of for example 12 V or 24 V.

The disclosure proposes a possibility for testing or monitoring whether the DC voltage source is still connected to the DC voltage contacts of the power converter assembly and thus to the remaining components of the drive system, or whether it has been disconnected therefrom, e.g. due to a defect or an accident.

For this purpose, a test circuit is provided, for example as part of the power converter assembly, which is connected in parallel with the DC voltage contacts and the DC link capacitor arrangement. The test circuit has in particular electrical or electronic components that are in particular directly integrated into the drive system or into the power converter assembly. The test circuit can for example be realised as an analogue unit or an analogue circuit, independently of a computing unit or independently of a control unit. However, it is also conceivable that the test circuit has logic components that can for example be integrated in a computing unit or a control unit for controlling the drive system.

Within the scope of the present method, an injection signal is generated by means of the test circuit. The generated injection signal is injected into the DC voltage side by means of the test circuit. In response to this injection, a voltage or current signal of the DC voltage side is determined as a test signal by means of the test circuit. The test circuit evaluates whether the test signal reaches a threshold value. Depending on this evaluation, it is determined whether the DC voltage source is connected to the DC voltage contacts and thus in particular to the DC link capacitor unit and the converter circuit or not. The test circuit can for example be integrated as a component into the power converter assembly itself or also be provided as an independent upstream module in addition to the power converter assembly.

The injection signal is in particular a sinusoidal signal, in particular a voltage or current signal. The injection signal can particularly usefully be injected into a network of impedances of the drive system. In particular, the injection signal can flow via an impedance of the DC voltage source as well as an impedance of cables by means of which the DC voltage source is connected to the DC voltage contacts, and thus close a control or measurement loop. When the DC voltage source is connected, these cables and the DC voltage source run in particular in parallel with the DC link capacitor arrangement. When the DC voltage source is disconnected, the impedance perceived by the test circuit changes in particular suddenly. In the process, the magnitude or amplitude of the determined test signal also changes in particular. When the test signal thereby reaches the corresponding threshold value, it can in particular be quickly and reliably concluded that the DC voltage source has been disconnected.

In order to monitor in a conventional manner whether a DC voltage source in a drive system has been disconnected, a voltage in a respective DC link can for example be monitored. When this DC link voltage exceeds a respective maximum value, disconnection of the DC voltage source can be inferred. However, this can be associated with a large delay of up to several hundred microseconds until, after the disconnection of the DC voltage source, the DC link voltage reaches the respective maximum value and until the disconnection of the DC voltage source can be detected.

In contrast, the present disclosure enables significantly faster detection of when the DC voltage source has been disconnected from the remaining components of the drive system, in particular already after a few microseconds. Thus, countermeasures can in particular be initiated significantly faster in order to avoid or at least reduce damage in the drive system.

According to one embodiment, the test circuit comprises a signal generation unit, a transformer unit, a capacitor unit, a sensor unit and an evaluation unit. The injection signal is generated by means of the signal generation unit. The injection of the generated injection signal into the DC voltage side of the drive system is performed by means of the transformer unit and the capacitor unit. The determination of the test signal is performed by means of the sensor unit. The evaluation of the test signal and the determination of whether the DC voltage source is still connected or not are performed by means of the evaluation unit. The signal generation unit is designed in particular as a voltage and/or current source. The signal generation unit is in particular connected to a primary side of the transformer unit. The capacitor unit is in particular connected to a secondary side of the transformer unit. The sensor unit is in particular connected between the signal generation unit and the transformer unit, either in parallel or in series depending on the specific embodiment of the signal generation unit. The sensor unit may comprise a sensor, e.g. a current and/or voltage sensor, as well as further in particular a circuit for processing the raw signal detected by means of the sensor. When the generated injection signal is injected into the transformer unit, the transformer unit can usefully provide galvanic isolation. On the secondary side of the transformer unit, the injection signal can usefully be coupled to the network of impedances of the drive system via the capacitor unit.

According to one embodiment, the test circuit further comprises a signal filter unit, in particular a band-pass filter unit, which is connected between the sensor unit and the evaluation unit. A pass-band frequency of this signal filter unit can be selected depending on or similar to a frequency of the generated injection signal, such that in particular only a relevant signal is passed to the evaluation unit. An output of the signal filter unit can be forwarded to a detection circuit of the evaluation unit. The correspondingly filtered test signal may in particular have a sinusoidal waveform and the magnitude or amplitude of the filtered test signal is monitored in particular for whether the threshold value is reached.

According to one embodiment, it is determined, assessed or detected that the DC voltage source is still connected to the DC voltage contacts when the test signal does not reach the threshold value and in particular lies below this threshold value. If, on the other hand, the test signal reaches or exceeds the threshold value, it is determined, assessed or detected that the DC voltage source is disconnected from the DC voltage contacts and thus in particular from the DC link capacitor unit and the converter circuit. Since the test signal reaches the corresponding threshold value significantly faster after a disconnection of the DC voltage source from the remaining components of the drive system than the DC link voltage reaches a respective maximum value, the disconnection of the DC voltage source can be detected significantly faster by monitoring the test signal than by conventional monitoring of the DC link voltage.

According to one embodiment, a voltage signal is generated as the injection signal and a current signal is determined as the test signal. In this case, the signal generation unit is usefully designed as a voltage source and the sensor unit is designed as a current sensor. Alternatively or additionally, a current signal can also be generated as the injection signal and a voltage signal can be determined as the test signal. In this case, the signal generation unit is usefully designed as a current source and the sensor unit is usefully designed as a voltage sensor. For example, it can be decided depending on electromagnetic compatibility whether a voltage and/or current signal is injected into the drive system as the injection signal.

According to one embodiment, the power converter assembly further comprises a filter unit, in particular an EMI filter for avoiding electromagnetic interference (EMI). This filter unit is connected in series between a first DC voltage contact of the two DC voltage contacts and the DC link capacitor arrangement, in particular on the supply potential side (not on the ground side). The filter unit has a plurality of inductance units, wherein these individual inductance units can each represent a stage of the EMI filter. The test circuit can be connected between the first DC voltage contact and the filter unit or between two inductance units of this plurality of inductance units of the filter unit. For example, depending on regulations, specifications or customer requirements, it can be flexibly decided at which point the test circuit is connected to the drive system and at which point the injection signal is thus injected into the drive system.

According to one embodiment, a signal with a predetermined maximum frequency and/or a predetermined maximum amplitude is generated as the injection signal. In particular, the amplitude and frequency of the injection signal are limited such that interference during operation of the drive system is avoided and EMI requirements can be met. Furthermore, as the frequency of the injection signal, no multiple of a switching frequency of the drive system or of the converter circuit is selected in particular. For example, the maximum frequency of the injection signal may be 150 kHz.

The test circuit may comprise a computing unit, e.g. a control unit, a microprocessor or microcontroller, which is configured, in particular by programming, to perform a method according to the disclosure. The computing unit according to the disclosure is in particular configured to control the individual components of the test circuit for executing the method according to the disclosure. However, it is also conceivable that the test circuit is designed as a purely analogue unit or a purely analogue circuit, independently of a computing unit or independently of a control unit.

The implementation of a method according to the disclosure in the form of a computer program or computer program product with program code for performing all method steps is also advantageous, since this incurs particularly low costs, especially when an executing control unit is also used for further tasks and is therefore already present in any case. The computer program may in particular be part of a microcontroller code. Suitable data carriers for providing the computer program are in particular magnetic, optical and electrical storage media, such as hard disks, flash memories, EEPROMs, DVDs, etc. A download of a program via computer networks (internet, intranet, etc.) is also possible.

Further advantages and embodiments of the disclosure will become apparent from the description and the accompanying drawing. The disclosure is illustrated schematically by means of exemplary embodiments in the drawing and is described below with reference to the drawing.

### BRIEF DESCRIPTION OF THE DRAWINGS

FIG. 1 shows schematically a drive system according to the prior art in a schematic circuit diagram view.

FIG. 2 shows schematically a time profile of a voltage that can be determined in a drive system according to the prior art.

FIG. 3 shows schematically a drive system which can form the basis of an embodiment of the method according to the disclosure, in various schematic circuit diagram views a) to c).

FIG. 4 shows schematically a time profile of a voltage, a current and a fault signal that can be determined in a drive system according to an embodiment of the method according to the disclosure.

### DETAILED DESCRIPTION

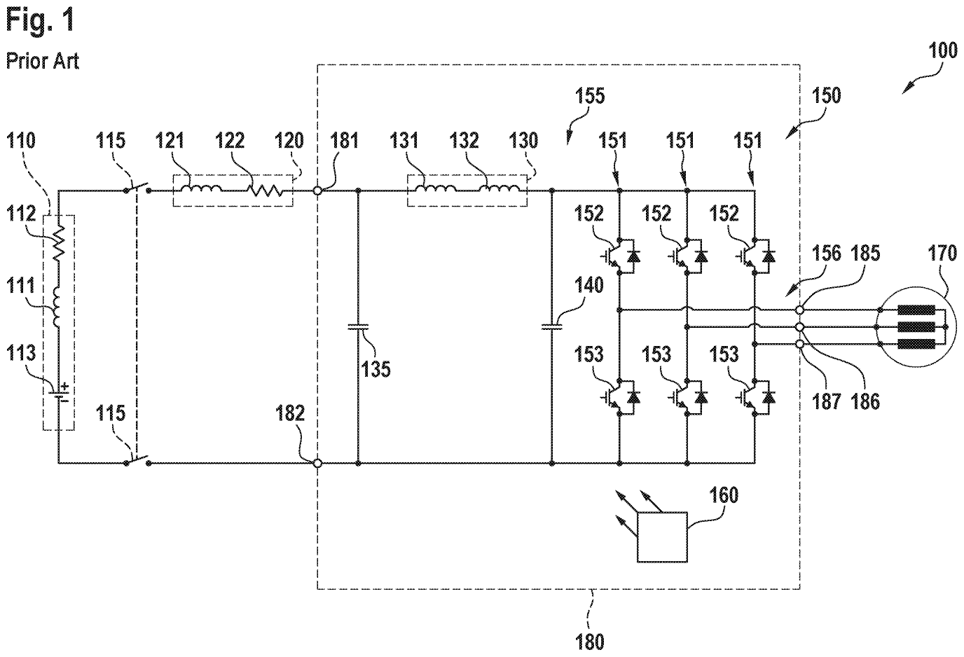

In FIG. 1, a drive system according to the prior art is illustrated schematically and in circuit diagram form, designated in its entirety by 100. The drive system 100 can for example be used in a vehicle as a traction drive.

The drive system 100 comprises a DC voltage source 110, e.g. a vehicle battery, as well as a multi-phase electric machine 170. A converter circuit 150 is provided for the rectification or inversion of current between the vehicle battery 110, which is connected to a DC voltage side 155 of the converter circuit 150, and the multi-phase electric machine 170, which is connected to an AC voltage side 156 of the converter circuit 150.

The converter circuit 150 has a plurality of half-bridges 151 (here three), each having a high-side switching element 152 and a low-side switching element 153, each of which can for example be designed as a metal-oxide-semiconductor field-effect transistor (MOSFET) or insulated-gate bipolar transistor (IGBT). A control unit 160 is provided for controlling the converter circuit 150, in particular for controlling the individual switching elements of the converter circuit 150. A DC link capacitor arrangement 140 is connected in parallel with the vehicle battery 110 and the converter circuit 150. In FIG. 1, the DC link capacitor arrangement 140 comprises by way of example one DC link capacitor, however the DC link capacitor arrangement 140 may also comprise a plurality of DC link capacitors.

The converter circuit 150, the control unit 160 and the DC link capacitor arrangement 140 may form a structural unit or a device (with housing) that is referred to as a power converter assembly or inverter 180. The inverter 180 has a first DC voltage contact 181 (B+) and a second DC voltage contact 182 (B−) for connection with the DC voltage source 110. Furthermore, the inverter 180 has AC voltage contacts 185, 186 and 187 for connection with the phases U, V, W of the electric machine 170.

The drive system 100 further has a filter unit 130, e.g. an EMI filter, which is connected in series between the vehicle battery 110 and the DC link capacitor arrangement 140 and has a plurality of inductance units 131, 132. Furthermore, a filter capacitor 135 may be provided. The drive system 100 may have further components, e.g. further filters, e.g. a pi filter. An equivalent circuit model of a cable connection between the vehicle battery 110 and the DC link capacitor arrangement 140 is designated by 120 in FIG. 1 and comprises an inductor or impedance 121 and a resistance unit 122. Furthermore, an equivalent circuit model of the vehicle battery 110 has an impedance 111, a resistance unit 112 and a voltage source 113. The DC voltage source 110 can be disconnected from the remaining drive system via switches 115.

In order to avoid the DC link capacitors 140 being charged via the electric machine 170, in particular when using a permanent-magnet synchronous motor (PMSM), an active short circuit (ASC) technique can be used. In the process, the energy transfer from the electric machine 170 into the DC link can be stopped by closing all low-side switches 153 or all high-side switches 152. In the event of an accident or a fault in the converter circuit 150, a functional safety circuit or logic can decide whether to switch to the active discharge mode and ASC. When a battery management system (BMS) disconnects the battery 110 from the other parts of the drive system 100, the switches 115 are opened.

This disconnection can occur due to a fault in the vehicle or an accident. The control unit 160 or the BMS can then inform other electrical components such as a DC/DC converter and the converter circuit 150 via CAN communication or other communication platforms that the battery 110 is disconnected. However, the speed of CAN is often not high enough to be used for safety functions of the converter circuit 150.

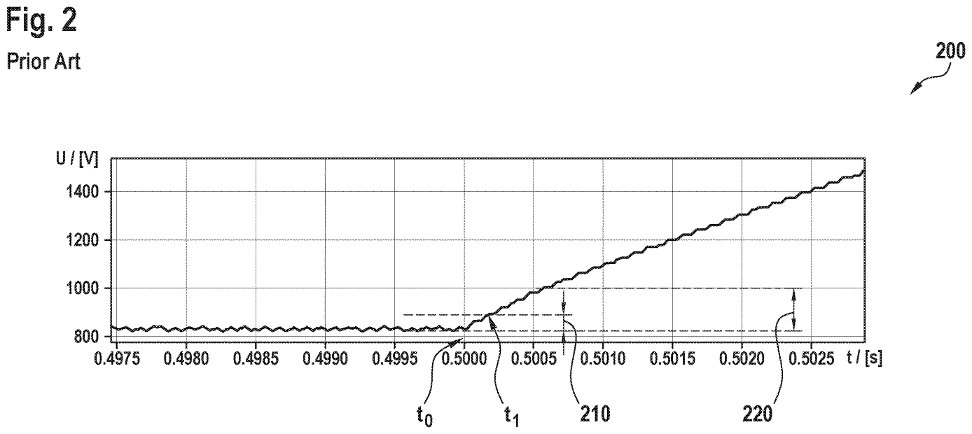

A particularly dangerous scenario can occur when the drive system 100 is operating in regenerative mode and the entire power is being transferred from the electric machine 170 to the battery 110. If the battery 110 is disconnected in this case, e.g. by opening the switches 115, due to an accident, defect, cable rupture, etc., all the energy can flow into the DC link, whereby the voltage of the DC link can rise rapidly, as explained below with reference to FIG. 2.

FIG. 2 shows schematically a profile 200 of a voltage U, in particular the DC link voltage, plotted against time t, which can be determined in the drive system 100 according to the prior art. The profile 200 represents the above-described case of maximum regenerative peak power, in which the entire power is transferred from the electric machine 170 to the battery 110. At a point in time to, the battery 110 is disconnected from the remaining components of the drive system and the switches 115 are opened. After this disconnection of the battery 110, the voltage rises from 830 V to over 1,000 V within a few microseconds. For example, reference numeral 210 designates a voltage rise of approx. 100 V, which corresponds to a gradient ΔV/Δt of 0.327 V/μs. Correspondingly, reference numeral 220 designates for example a voltage rise of approx. 200 V, which corresponds to a gradient ΔV/Δt of 0.298 V/μs.

In order to detect the battery disconnection in a conventional manner, it is possible for example to monitor whether the DC link voltage exceeds a permissible maximum value of e.g. 920 V. However, this can be associated with a significant time delay. Thus, in the example of FIG. 2, the DC link voltage does not reach this permissible maximum value of 920 V until a point in time t₁, wherein this point in time t₁ occurs 270 μs after the point in time to of the battery disconnection.

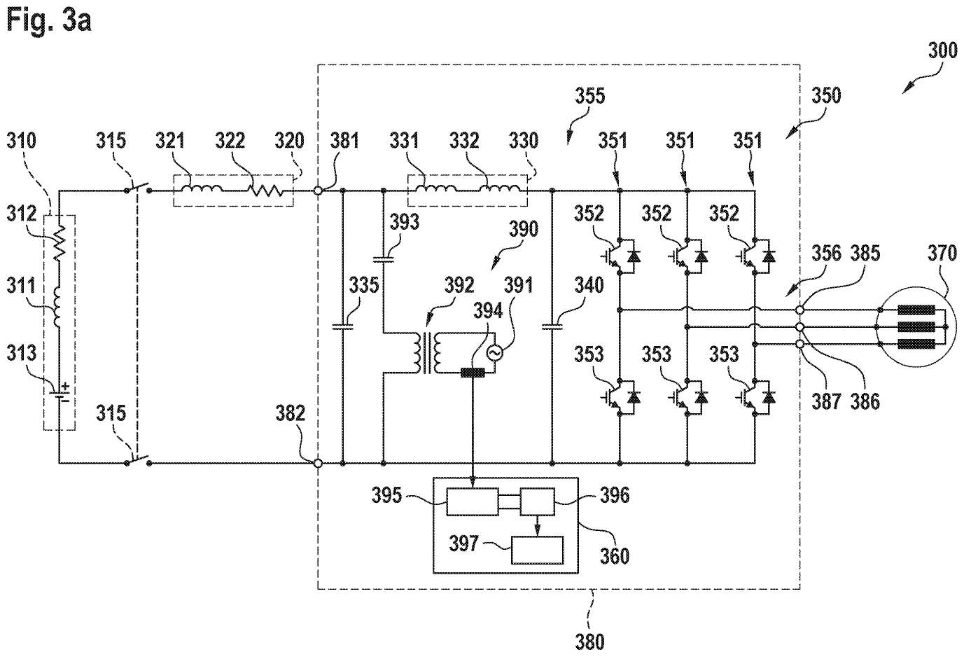

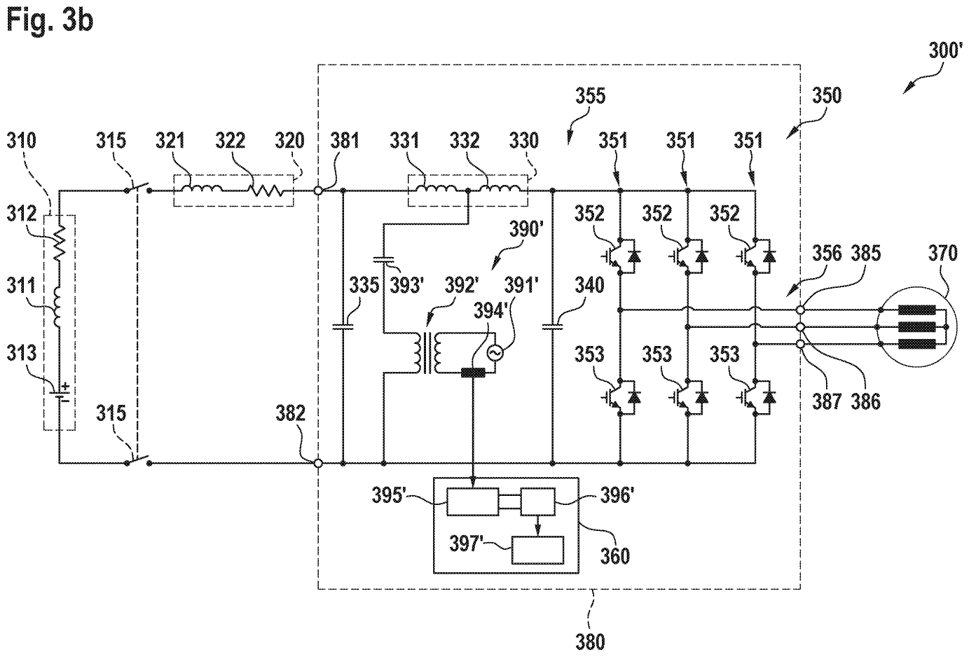

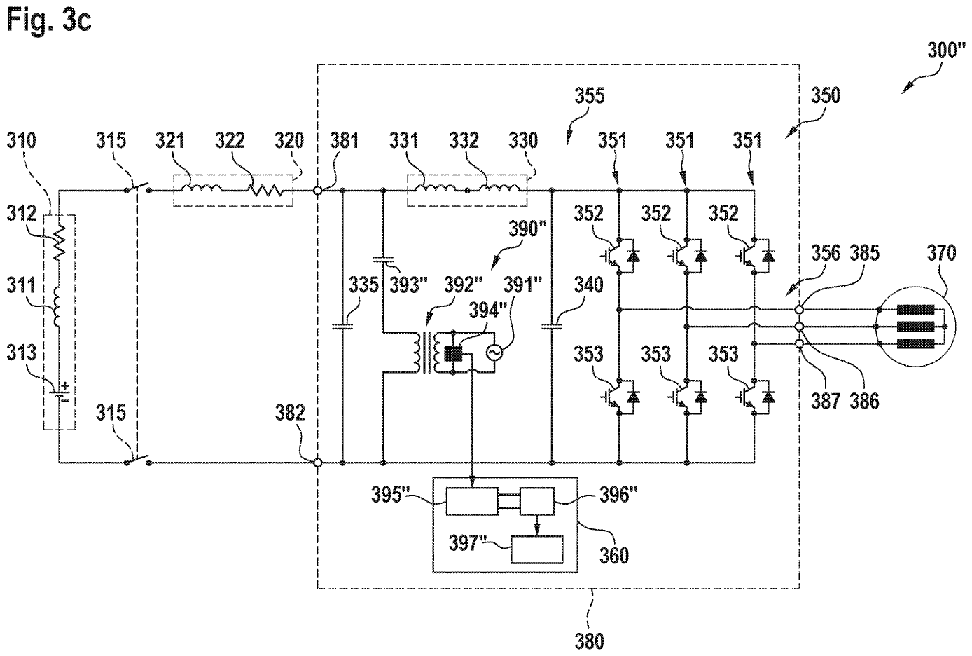

Instead of relying exclusively on such detection of a battery disconnection on the basis of overvoltage or on a signal via CAN or a communication channel, the disclosure proposes a significantly faster and more reliable method for detecting a battery disconnection and thus providing more time for control measures such as ASC, as explained below with reference to FIGS. 3a to 3c.

FIG. 3a shows schematically a drive system 300 which can form the basis of an embodiment of the method. Identical or structurally identical elements of the drive system 300 shown in FIG. 3a compared to the drive system 100 according to the prior art from FIG. 1 are each designated by a reference numeral increased by the value “200” and are not all explicitly explained again in order to avoid repetition.

The drive system 300 thus also has a DC voltage source 310, e.g. a vehicle battery, and a power converter assembly or inverter 380, wherein the battery 310 is connected to the DC voltage contacts 381, 382 of the inverter 380 by means of cables or lines. An equivalent circuit model for these cables is designated by 320. The inverter 380 has a DC link capacitor arrangement 340 connected in parallel with the DC voltage contacts 381, 382 and thus in parallel with the battery 310, and a converter circuit 350 connected in parallel with the DC link capacitor arrangement 340, with a DC voltage side 355 and an AC voltage side 356.

In order to test whether the battery 310 is still connected to the remaining components of the drive system 300 and whether the switches 315 are still closed, a test circuit 390 is connected in parallel with the DC voltage contacts 381, 382 and the DC link capacitor arrangement 340.

This test circuit 390 comprises for example a signal generation unit 391, e.g. a voltage or current source, for generating a sinusoidal voltage or current signal as an injection signal. A transformer unit 392 and a capacitor unit 393 can be provided in order to inject the generated injection signal into the drive system 300 or more precisely the DC voltage side 355 of the drive system 300. A sensor unit can have a current sensor 394 and a sensor circuit 395 and be configured to detect a test signal, e.g. a current or voltage signal, in response to the injection of the injection signal. An evaluation unit 397 can be provided to evaluate the test signal. Furthermore, a signal filter unit 396, e.g. a band-pass filter unit, can be connected between the sensor unit 394, 395 and the evaluation unit 397. The sensor circuit 395, the signal filter unit 396 and the evaluation unit 397 can for example be implemented as components in a computing unit 360 such as a microcontroller. However, it is also conceivable that the test circuit 390 is designed as an analogue unit or an analogue circuit, independently of a computing unit.

The evaluation unit 397 can evaluate the test signal to determine whether the test signal reaches a threshold value. Depending on this evaluation, the evaluation unit 397 can test whether the battery 310 is still connected to the DC link capacitor unit 340 and the converter circuit 350 or not. If the test signal does not reach the threshold value and lies below the threshold value, the evaluation unit 397 determines for example that the battery 310 is still connected and that the switches 315 are still closed. If, on the other hand, the test signal reaches and exceeds the threshold value, the evaluation unit 397 determines for example that the battery 310 is no longer connected and that the switches 315 are open.

By means of the test circuit 390, a sinusoidal signal with very low amplitude can thus be injected in order to avoid interference during operation of the drive system 300 and to be able to meet EMI requirements. For example, the frequency of the injection signal can be below 150 kHz and not a multiple of the switching frequency. For example, the frequency of the injection signal can be 143 kHz and the switching frequency of the drive system 300 can be 10 kHz. A network of impedances of the drive system 300 can be composed of the impedances 311, 321, 331 of the battery 310, the cables 320 and the EMI filter 330. Since the resistance 312 of the battery 310 and the resistance 322 of the cables 320 are very low, the inductances 311, 321, 331 of the battery 310, the cables 320 and the EMI filter 330 can be assumed to be the dominant components for the impedance network. When the injection signal is injected from the signal generation unit 391 into the transformer unit 392, the transformer unit 392 can provide galvanic isolation. On the secondary side of the transformer unit 392, the injection signal can be coupled to the impedance network of the drive system 300 via the capacitor unit 393.

A monitoring current can thus flow and close a control loop or measurement loop via the battery impedance 311 and the impedance 321 of the cables 320. Additionally, a part of this monitoring current can flow via differential-mode inductances.

Typically, EMI filters can have X-capacitors, Y-capacitors, differential-mode inductance and common-mode inductance. Since the injection signal is present in particular in a differential mode between the positive and the negative conductor, the common-mode choke exhibits in particular no effect or can act as a leakage inductance that is added to the differential-mode inductances or plays only the role of differential-mode inductances. Therefore, such a common-mode choke is not explicitly shown in FIG. 3a for the sake of clarity.

If the injection signal is a voltage signal as in the example of FIG. 3a, the test signal can be measured as a current signal by means of the sensor 394 and passed through the band-pass filter 396. The pass-band frequency of the band-pass filter 396 is in particular similar to the frequency of the injection signal in order to ensure that only a relevant measured signal is passed to the evaluation unit 397. The output of the band-pass filter 396 can be forwarded to a detection circuit of the evaluation unit 397. The filtered test signal can for example have a sinusoidal waveform. The magnitude or amplitude of the test signal is compared with the corresponding threshold value.

When the battery 310 is connected, the cables 320 and the battery 310 run in particular in parallel with the EMI filter 330 and with the DC link capacitor arrangement 340. When the battery 310 is disconnected, the impedance perceived by the signal generation unit 391 changes suddenly. Therefore, the magnitude of the test signal also changes.

In the example of FIG. 3a, the injection of the injection signal takes place within the inverter 380 between the first DC voltage contact 381 (B+) and the EMI filter 330. If, e.g. due to regulations, specifications or customer requirements, the injection is not possible there, the injection can also take place between two stages of the EMI filter 330, as explained below with reference to FIG. 3b.

FIG. 3b shows schematically a drive system 300′ according to one embodiment. Identical reference numerals in FIGS. 3a and 3b denote structurally identical elements. The drive system 300′ also has a test circuit 390′ with a signal generation unit 391′, a transformer unit 392′, a capacitor unit 393′, a sensor unit consisting of a sensor 394′ and a sensor circuit 395′, a signal filter unit 396′ and an evaluation unit 397′. In contrast to the test circuit 390 from FIG. 3a, which is connected between the first DC voltage contact 381 or B+and the filter unit 330 of the drive system 300, the test circuit 390′ from FIG. 3b is connected between the two inductance units 331, 332 of the EMI filter unit 330.

The signal generation units 391 and 391′ of the test circuits 390 and 390′ are each designed as voltage sources for generating a voltage signal as the injection signal, and the sensors 394 and 394′ are each designed as current sensors for determining a current signal as the test signal. However, it is also conceivable to generate a current signal as the injection signal and to determine a voltage signal as the test signal, as explained below with reference to FIG. 3c.

FIG. 3c also shows schematically a drive system 300″ according to one embodiment, wherein identical reference numerals in FIGS. 3a, 3b and 3c denote structurally identical elements. The drive system 300″ also has a test circuit 390″ which comprises a signal generation unit 391″, a transformer unit 392″, a capacitor unit 393″, a sensor unit with sensor 394″ and sensor circuit 395″, a signal filter unit 396″ and an evaluation unit 397″. In contrast to the test circuits 390 and 390′, the signal generation unit 391″ of the test circuit 390″ is designed as a current source for generating a current signal as the injection signal. The sensor 394″ is designed as a voltage sensor for determining a voltage signal as the test signal.

Although a three-phase electric machine 370 and a corresponding three-phase converter circuit 350 are illustrated in each of FIGS. 3a, 3b and 3c purely by way of example, it is understood that the disclosure is not intended to be limited to such three-phase drive systems, but is in particular also suitable for drive systems with more than three phases.

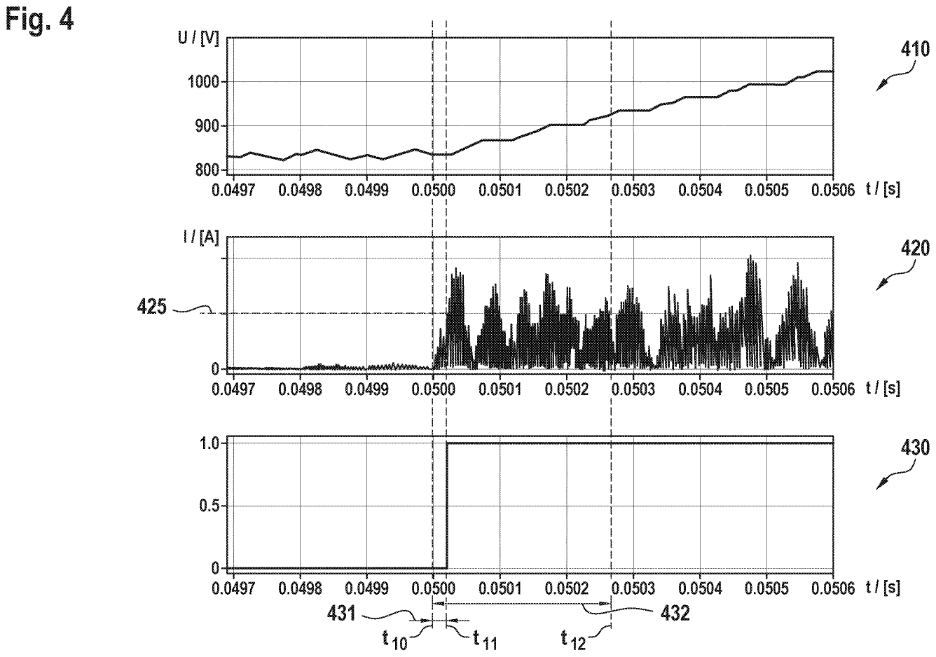

FIG. 4 shows a profile 410 of a voltage, a profile 420 of a current I and a profile 430 of a fault signal, each plotted against time t, which can for example be determined with the drive system 300 shown in FIG. 3a within the scope of one embodiment. The voltage profile 410 corresponds for example to a time profile of a DC link voltage of the drive system 300. The current profile 420 corresponds for example to the test signal designed as a current signal, which can be determined by means of the test circuit 390. When the fault signal 430 takes the value “0”, this means that the battery 310 is connected in the drive system 300. When the fault signal 430 takes the value “1”, this means that the battery 310 is disconnected in the drive system 300.

In FIG. 4, as in FIG. 2, the case of maximum regenerative peak power is shown, in which the entire power is transferred from the electric machine 370 to the battery 310. At a point in time t₁₀, the battery 310 is disconnected from the remaining components of the drive system 300, e.g. by opening the switches 315 or due to an accident, defect, cable rupture, etc. As already explained above with reference to FIG. 2, after this disconnection of the battery 110, the DC link voltage U rises from 830 V to over 1,000 V within a few microseconds.

As can be seen in the time profile 420 of the current test signal, the value of the determined current signal prior to battery disconnection is well below the threshold value designated by 425. After the disconnection of the battery 310, the value of the test signal changes considerably due to the change in the impedance of the network and exceeds the threshold value 425 at point in time t₁₁. In the example of FIG. 4, the change in the test signal takes place in the positive direction by way of example, however in other cases the determined test signal may also decrease considerably after battery disconnection.

Due to the threshold value 425 being exceeded at point in time t₁₁, the test circuit 390 detects significant impedance changes caused by the disconnection of the battery 310, such that the fault signal 430 rises from the value “0” to the value “1” at point in time t₁₁. The battery disconnection can thus be detected after a time interval 431 of 20 μs. By comparison, t₁₂ indicates the point in time at which the DC link voltage U reaches the respective permissible maximum value of e.g. 920 V, which can conventionally be used to detect the battery disconnection. In this conventional manner, the battery disconnection can only be detected after a time interval 432 of 270 μs. By means of the disclosure, a battery disconnection can thus be detected significantly faster, more reliably and more efficiently than with conventional methods.

Fluctuations in the current profile 420 can result in the measured current being able to fall below the threshold value 425 again after first reaching the threshold value 425. A special mechanism can therefore for example be used, which is activated after first reaching the threshold value 425. This mechanism can after its activation be reset for example by the computing unit 360 or by the transmitted fault signal 430 or by an external command from a further vehicle control unit.

1. A method for testing a DC voltage source (310) in a drive system (300, 300′, 300″), in particular in a vehicle, wherein the drive system (300, 300′, 300″) has the DC voltage source (310) and a power converter assembly (380) with two DC voltage contacts (381, 382), wherein the DC voltage source (310) is connected in parallel with the DC voltage contacts (381, 382) of the power converter assembly (380), wherein the power converter assembly (380) has a DC link capacitor arrangement (340) connected in parallel with the DC voltage contacts (381, 382) and a converter circuit (350) connected in parallel with the DC link capacitor arrangement (340), with a DC voltage side (355) and an AC voltage side (356), wherein a test circuit (390, 390′, 390″) is connected on the DC voltage side (355) in parallel with the DC voltage contacts (381, 382) and the DC link capacitor arrangement (340), wherein the method comprises the following steps:
generating an injection signal by means of the test circuit (390, 390′, 390″);
injecting the generated injection signal by means of the test circuit (390, 390′, 390″) into the DC voltage side (355);
determining a voltage or current signal on the DC voltage side (355) as a test signal (420) in response to the injection of the injection signal by means of the test circuit (390, 390′, 390″);
evaluating the test signal (420) by means of the test circuit (390, 390′, 390″) as to whether the test signal (420) reaches a threshold value (425);
determining whether the DC voltage source (310) is connected to the DC voltage contacts (381, 382) or not, depending on the evaluation of the test signal (420).

2. The method according to claim 1, wherein the test circuit (390, 390′, 390″) has a signal generation unit (391, 391′, 391″), a transformer unit (392, 392′, 392″), a capacitor unit (393, 393′, 393″), a sensor unit (394, 394′, 394″, 395, 395′, 395″) and an evaluation unit (397, 397′, 397″), wherein the generation of the injection signal is performed by means of the signal generation unit (391, 391′, 391″);
wherein the injection of the generated injection signal into the DC voltage side (355) is performed by means of the transformer unit (392, 392′, 392″) and the capacitor unit (393, 393′, 393″);
wherein the determination of the test signal (420) is performed by means of the sensor unit (394, 394′, 394″, 395, 395′, 395″);
wherein the evaluation of the test signal (420) is performed by means of the evaluation unit (397, 397′, 397″);
wherein the determination of whether the DC voltage source (310) is connected to the DC voltage contacts (381, 382) or not is performed by means of the evaluation unit (397, 397′, 397″).

3. The method according to claim 2, wherein the test circuit (390, 390′, 390″) further has a signal filter unit (396, 396′, 396″), in particular a band-pass filter unit, which is connected between the sensor unit (394, 394′, 394″, 395, 395′, 395″) and the evaluation unit (397, 397′, 397″).

4. The method according to claim 1, wherein the determining of whether the DC voltage source (310) is connected to the DC voltage contacts (381, 382) or not comprises:
determining that the DC voltage source (310) is connected to the DC voltage contacts (381, 382) when the test signal (420) does not reach the threshold value (425);
determining that the DC voltage source (310) is disconnected from the DC voltage contacts (381, 382) when the test signal (420) reaches the threshold value (425).

5. The method according to claim 1, wherein a voltage signal is generated as the injection signal and a current signal is determined as the test signal (420);
and/or wherein a current signal is generated as the injection signal and a voltage signal is determined as the test signal.

6. The method according to claim 1,
wherein the power converter assembly (380) further has a filter unit (330), in particular an EMI filter, wherein this filter unit (330) is connected in series between a first DC voltage contact (381) of the DC voltage contacts (381, 382) and the DC link capacitor arrangement (340), wherein the filter unit (330) has a plurality of inductance units (331, 332),
wherein the test circuit (390, 390″) is connected between the first DC voltage contact

(381) of the DC voltage contacts (381, 382) and the filter unit (330), or wherein the test circuit (390′) is connected between two inductance units (331, 332) of the plurality of inductance units of the filter unit (330).

7. The method according to claim 1, wherein a signal with a predetermined maximum frequency and/or a predetermined maximum amplitude is generated as the injection signal.

8. A test circuit (390, 390′, 390″) for testing a DC voltage source (310) in a drive system (300, 300′, 300″),
wherein the drive system (300, 300′, 300″) has the DC voltage source (310) and a power converter assembly (380) with two DC voltage contacts (381, 382),
wherein the DC voltage source (310) is connected in parallel with the DC voltage contacts (381, 382) of the power converter assembly (380),
wherein the power converter assembly (380) has a DC link capacitor arrangement (340) connected in parallel with the DC voltage contacts (381, 382) and a converter circuit (350) connected in parallel with the DC link capacitor arrangement (340), with a DC voltage side (355) and an AC voltage side (356),
wherein the test circuit (390, 390′, 390″) is configured to be connected in the drive system (300, 300′, 300″) in parallel with the DC voltage contacts (381, 382) of the power converter assembly (380), wherein the test circuit (390, 390′, 390″) is configured to execute claims. the method according to claim 1.

9. The test circuit (390, 390′, 390″) according to claim 8, further comprising:
a signal generation unit (391, 391′, 391″) configured to generate an injection signal;
a transformer unit (392, 392′, 392″) and a capacitor unit (393, 393′, 393″) configured to inject the generated injection signal into the DC voltage side (355);
a sensor unit (394, 394′, 394″, 395, 395′, 395″) configured to determine, in response to the injection of the injection signal, a voltage or current signal on the DC voltage side (355) as a test signal;
and an evaluation unit (397, 397′, 397″) configured to evaluate the test signal and, depending on this evaluation, to determine whether the DC voltage source (310) is connected to the DC link capacitor arrangement (340) or not.

10. The test circuit (390, 390′, 390″) according to claim 8, further comprising a computing unit (360).

11. A power converter assembly (380) for controlling a multi-phase electric machine (370), comprising:
two DC voltage contacts (381, 382) configured to be connected to a DC voltage source (310),
a converter circuit (350) with a DC voltage side (355) and an AC voltage side (356), wherein the DC voltage side (355) has the DC voltage contacts (381, 382), a DC link capacitor arrangement (340),
and the test circuit (390, 390′, 390″) according to claim 8.

12. A drive system (300, 300′, 300″) with a power converter assembly according to claim 11 and a multi-phase electric machine (370) connected to the AC voltage side (356) of the converter circuit (350).

13. A non-transitory computer-readable data carrier on which a computer program is stored that comprises instructions which, when the program is executed by the computing unit (360) of the test circuit (390, 390′, 390″) cause it to execute the method according to claim 1.
